(19) United States
(12) Patent Application Publication
(10) Pub. No.: US 2021/0355600 A1
(43) Pub. Date: Nov. 18, 2021

(54) HEAT SHIELD DEVICE FOR LOW OXYGEN SINGLE CRYSTAL GROWTH OF SINGLE CRYSTAL INGOT GROWTH DEVICE

(71) Applicant: YOUNGDO GLOBAL CO., LTD., Asan-si (KR)

(72) Inventors: Tae Gyu KIM, Cheonan-si (KR); Cheol Woo LEE, Pyeongtaek-si (KR); Ui Seock LEE, Seoul (KR)

(21) Appl. No.: 17/242,625

(22) Filed: Apr. 28, 2021

(30) Foreign Application Priority Data
May 18, 2020 (KR) 10-2020-0058927

(51) Int. Cl. C30B 15/12; C30B 15/14; C30B 15/20; C30B 29/06

(52) U.S. Cl. CPC C30B 15/12; C30B 29/06; C30B 15/20; C30B 15/14

(57) ABSTRACT

An embodiment of the present invention provides a heat shield device for low oxygen single crystal growth of a single crystal ingot growth device, including: a crucible containing a silicon melt; a graphite crucible surrounding the crucible; a heat shield made of a low-emissivity (emissivity<0.3) material that surrounds a central lower portion of the graphite crucible and is spaced apart from the graphite crucible by a predetermined distance; and a connection part connecting the heat shield and the graphite crucible. Through the heat shield device according to the first embodiment of the present invention and the heat shield coating according to the second embodiment of the present invention, the concentration of oxygen flowing into the crystal may be reduced by lowering the temperature of the bottom of the crucible during the crystal growth, and the yield may be improved by reducing the BMD concentration in the semiconductor device through the growth of high-quality and low-oxygen single crystal.

### CROSS-REFERENCE TO RELATED APPLICATION

This application claims priority to and the benefit of Korean Patent Application No. 10-2020-0058927 filed in the Korean Intellectual Property Office on May 18, 2020, the entire contents of which are incorporated herein by reference.

### BACKGROUND OF THE INVENTION

### (a) Field of the Invention

The present invention relates to a single crystal ingot growth device, and more particularly, to a heat shield device for low oxygen single crystal growth of a single crystal ingot growth device that may grow a crystal at a low oxygen concentration by lowering a temperature of a quartz crucible to substantially suppress oxygen generated in the crucible.

### (b) Description of the Related Art

Generally, single crystal silicon is manufactured by the Czochralski (CZ) method, wherein after melting polycrystalline silicon in a crucible, a single crystal seed is brought into contact with the melt, and a single crystal is gradually extracted and grown.

A wafer obtained by cutting such a single crystal into a plate-like shape is used as a semiconductor substrate.

When designing a semiconductor circuit, it should be formed in a denuded zone in which there is no bulk microdefect on a surface of the substrate, and a substrate with a low oxygen concentration must be used to form such a denuded zone.

Since oxygen in the silicon single crystal is easily bonded to silicon dioxide (SiO₂) to form defects and is not removed from the surface of the substrate, as the oxygen increases, the formation of the denuded zone on the surface thereof is difficult.

In the Czochralski process, techniques for lowering the oxygen concentration have been variously researched.

In the Czochralski crystal growth, oxygen in the crystal is generated in a quartz crucible used as a container for melting polycrystals, and it is known that about 99% of this oxygen is volatilized through a melt surface, and 1% thereof is inflowed as crystals.

Meanwhile, an apparatus for manufacturing the single crystal silicon includes a heat insulating material in a chamber, a heater of a graphite material, a heat shield reflector, a quartz crucible, and a water cooling jacket.

Monocrystalline silicon is formed by placing polysilicon in the quartz crucible and heating it to a liquid state, and then gradually cooling the crystal as it grows from the liquid to a single crystal, and defects in the crystal grow according to a temperature profile during the cooling. In this case, atomic defects in the crystal during crystal growth and impurities such as oxygen are combined to grow at a microscale, or grow into a bulk microdefect in a device process in the future.

Here, the occurrence of oxygen concentration is shown in FIG. 1.

Referring to FIG. 1, the oxygen is generated in the quartz crucible, and as it moves by convection and diffusion along the silicon melt, about 99% of oxygen is volatilized, and about 1% of oxygen flows into the crystal. In this case, there is a high possibility that the oxygen generated at the bottom of the quartz crucible may flow into the crystal, and there is a high possibility that the oxygen generated from the side surface of the quartz crucible may be relatively volatilized on the melt surface.

Therefore, as a method to reduce the oxygen concentration flowing into the crystal, the conventional art has been variously developed for reducing the oxygen concentration at the bottom of the crystal.

The conventional art for suppressing oxygen concentration is mainly to shorten the length of the heater or change the main heating part to the upper part, thereby suppressing the oxygen concentration. That is, like the short heater and the short range heating heater of FIG. 2, it is a method of suppressing the generation of a lot of oxygen from the bottom by heating the side surface of the quartz crucible rather than the bottom thereof.

In Korean Patent Publication No. 2009-0008969, like the short range heating heater in FIG. 2, a method of lowering the oxygen concentration by making a groove on the heater at 20 to 40 mm of the upper melt surface to increase the electrical resistance and thus to locally heat only the upper part, and a method of lowering the temperature of the lower part of the quartz crucible by removing the lower insulation, are well disclosed.

Therefore, when the temperature of the upper side surface is relatively higher than the bottom of the quartz crucible, a lot of oxygen is generated from the side surface of the crucible, and the generated oxygen is easily volatilized, thereby reducing oxygen inflow to the crystal.

FIG. 3 shows a simulation result for a temperature change between a general heater and a short range heater.

As can be seen from FIG. 3, it can be seen that the maximum heating part of the upper heating heater is moved to the upper part of the heater disclosed in the prior art patent, and accordingly, the temperature of the bottom surface of the quartz crucible is relatively lowered. In this case, it can be seen that the oxygen concentration value of the crystal is decreased from 13 ppma to 12.1 ppma, similar to that disclosed in the prior art patent, as shown in FIG. 4.

The above information disclosed in this Background section is only for enhancement of understanding of the background of the invention, and therefore it may contain information that does not form the prior art that is already known in this country to a person of ordinary skill in the art.

### SUMMARY OF THE INVENTION

The present invention has been made in an effort to provide a heat shield device for low oxygen single crystal growth of a single crystal ingot growth device that may substantially grow crystals at a low oxygen concentration by lowering a temperature of a bottom surface of a quartz crucible to suppress generation of oxygen.

In addition, the present invention has been made in an effort to provide a heat shield device for low oxygen single crystal growth of a single crystal ingot growth device that may reduce an oxygen concentration that flows into a crystal during Czochralski crystal growth by lowering a temperature of a bottom surface of a quartz crucible to reduce the oxygen concentration.

That is, the present invention has been made in an effort to provide a heat shield device for low oxygen single crystal growth of a single crystal ingot growth device that may lower an oxygen concentration to 11 ppma or less by decreasing oxygen that inflows directly from a bottom surface of a quartz crucible to a crystal through a heat shielding device.

Furthermore, the present invention has been made in an effort to provide a heat shield device for low oxygen single crystal growth of a single crystal ingot growth device that may grow a single crystal with a sufficiently low concentration of oxygen by overlapping several blocking films or applying a blocking film together with a short range heater and that may contribute to improving yield by reducing a BMD concentration in a semiconductor device through high-quality and low-oxygen single crystal growth.

An embodiment of the present invention provides a heat shield device for low oxygen single crystal growth of a single crystal ingot growth device, including: a crucible containing a silicon melt; a graphite crucible surrounding the crucible; a heat shield made of a low-emissivity (emissivity<0.3) material that surrounds a central lower portion of the graphite crucible and is spaced apart from the graphite crucible by a predetermined distance; and a connection part connecting the heat shield and the graphite crucible,

The heat shield device for low oxygen single crystal growth of the single crystal ingot growth device may further include a heater heating a side surface of the crucible.

When the heater heats the side surface of the graphite crucible, it may heat each 25% thereof from a center thereof to upper and lower portions thereof.

The heat shield may include one or more heat blocking films. Another embodiment of the present invention provides a heat shield device for low oxygen single crystal growth of a single crystal ingot growth device, including: a crucible containing a silicon melt; and a graphite crucible surrounding the crucible, wherein a low emissivity (emissivity<0.3) material is coated from a center of the graphite crucible to a lower portion thereof.

The heat shield device for low oxygen single crystal growth of the single crystal ingot growth device may further include a heater heating a side surface of the crucible.

When the heater heats the side surface of the graphite crucible, it may heat each 25% thereof from a center thereof to upper and lower portions thereof.

According to the embodiment of the present invention, it is possible to provide a heat shield device for low oxygen single crystal growth of a single crystal ingot growth device that may substantially grow crystals at a low oxygen concentration by lowering a temperature of a quartz crucible to suppress generation of oxygen.

In addition, according to the embodiment of the present invention, it is possible to provide a heat shield device for low oxygen single crystal growth of a single crystal ingot growth device that may easily secure a sufficient level of a denuded zone by lowering a density of bulk microdefects (BMD) in a semiconductor device and may reduce a concentration of oxygen flowing into a crystal during Czochralski crystal growth by reducing generation of oxygen in a quartz crucible.

In addition, according to the embodiment of the present invention, it is possible to provide a heat shield device for low oxygen single crystal growth of a single crystal ingot growth device that may lower an oxygen concentration to 11 ppma or less by reducing a temperature of a bottom surface of a quartz crucible through a heat blocking film to reduce generation of oxygen directly flowing into a crystal.

Furthermore, according to the embodiment of the present invention, it is possible to provide a heat shield device for low oxygen single crystal growth of a single crystal ingot growth device that may grow a single crystal with a further low concentration of oxygen by overlapping several blocking films or applying a blocking film together with a short range heater and that may contribute to improving yield by reducing a BMD concentration in a semiconductor device through high-quality and low-oxygen single crystal growth.

### BRIEF DESCRIPTION OF THE DRAWINGS

FIG. 1 illustrates oxygen generation in a general single crystal manufacturing apparatus.

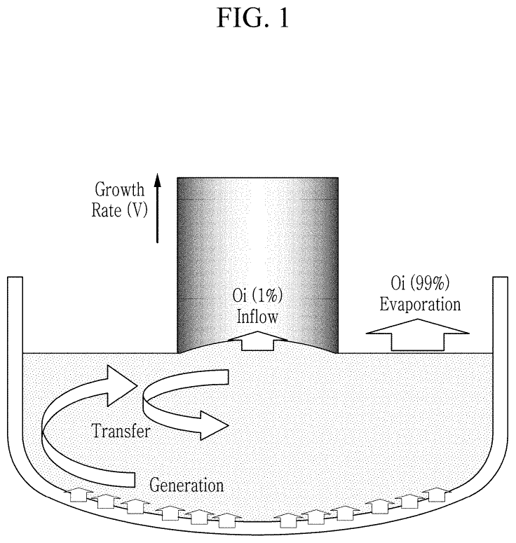

FIG. 2 illustrates examples of heating a crucible with a general heater, a short heater, and a short range heater.

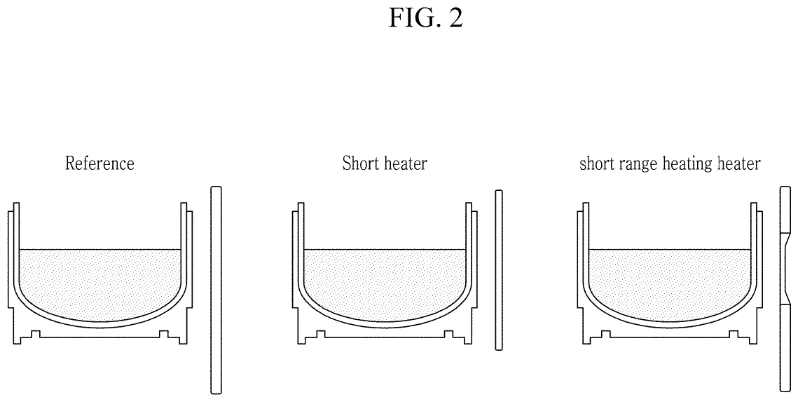

FIG. 3 illustrates a temperature of a bottom of a crucible when the crucible is heated with a general heater and a short range heater.

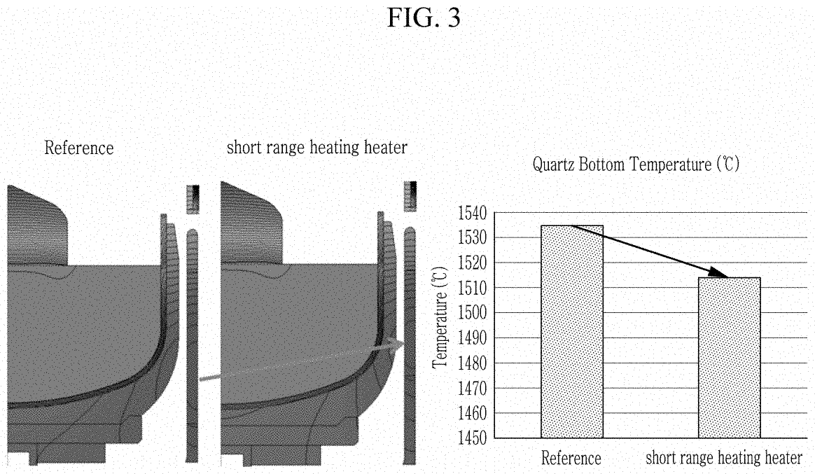

FIG. 4 illustrates an oxygen concentration generated when the crucible is heated with a general heater and a short range heater.

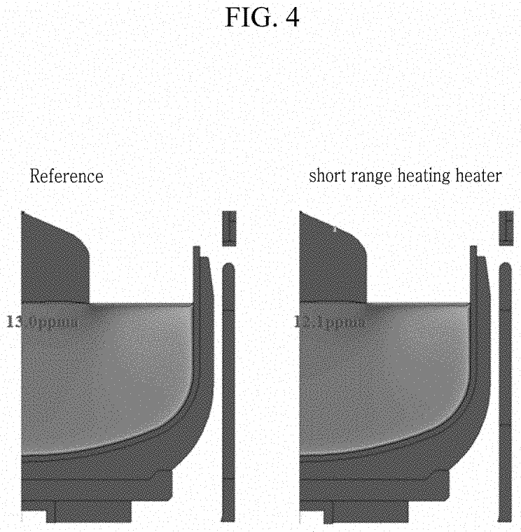

FIG. 5 illustrates a heat shield device for low oxygen single crystal growth of a single crystal ingot growth device according to a first embodiment of the present invention.

FIG. 6 illustrates a heat shield device for low oxygen single crystal growth of a single crystal ingot growth device according to a second embodiment of the present invention.

FIG. 7 illustrates a temperature and oxygen concentration at a bottom of a crucible when a heat shield of the first embodiment and a heat shield coating of the second embodiment are applied.

FIG. 8 illustrates an oxygen concentration when a general long heater, a short range heater, a moly heat shield #1, a moly heat shield #2, a low E coating condition, the short range heater+the moly heat shield #1, the short range heater+the low E coating are applied.

### DETAILED DESCRIPTION OF THE EMBODIMENTS

The present invention will be described more fully hereinafter with reference to the accompanying drawings, in which an exemplary embodiment of the invention is shown. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

Throughout the specification, unless explicitly described to the contrary, the word “comprise” and variations such as “comprises” or “comprising” will be understood to imply the inclusion of stated elements but not the exclusion of any other elements.

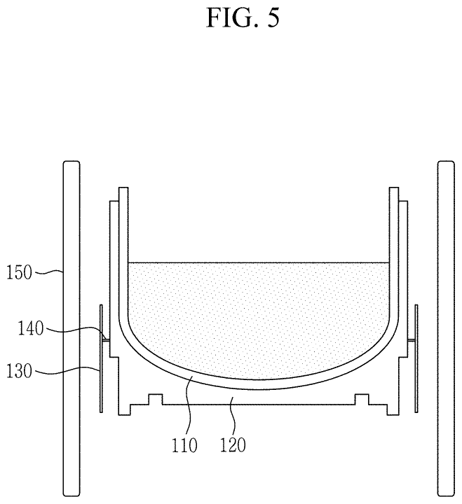

FIG. 5 illustrates a heat shield device for low oxygen single crystal growth of a single crystal ingot growth device according to a first embodiment of the present invention.

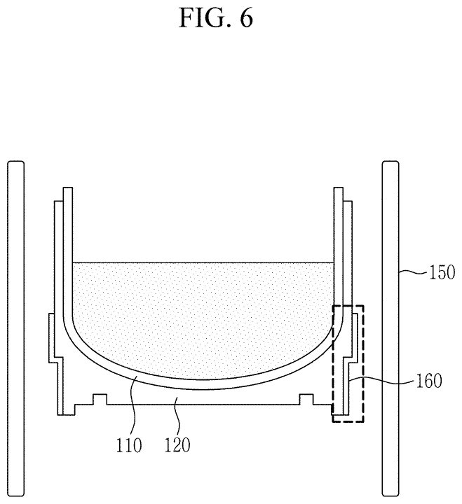

FIG. 6 illustrates a heat shield device for low oxygen single crystal growth of a single crystal ingot growth device according to a second embodiment of the present invention.

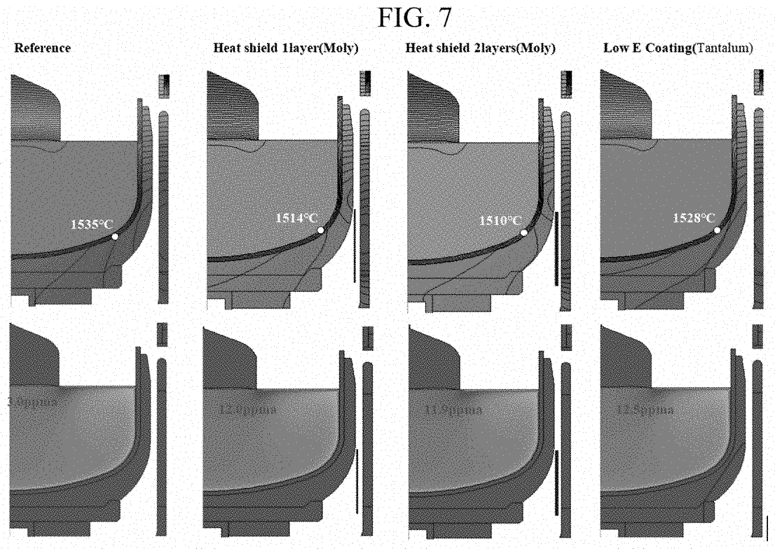

FIG. 7 illustrates a temperature and oxygen concentration at a bottom of a crucible when a heat shield of the first embodiment and a heat shield coating of the second embodiment are applied.

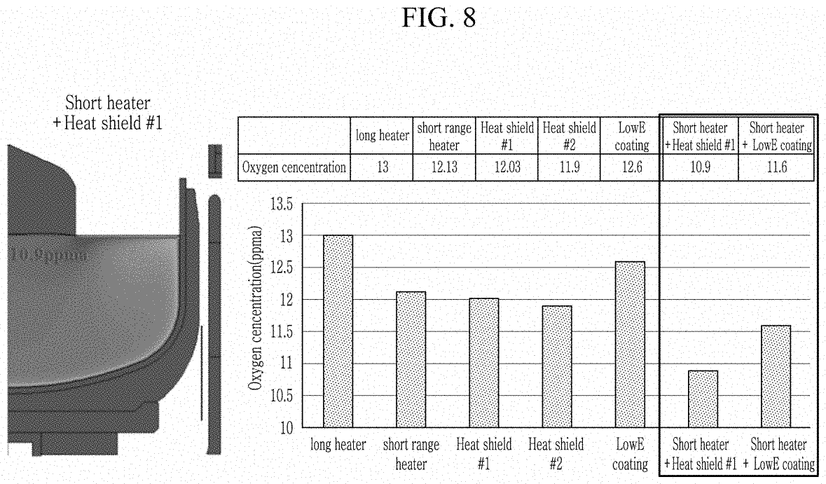

FIG. 8 illustrates an oxygen concentration when a general long heater, a short range heater, a moly heat shield #1, a moly heat shield #2, a low emissivity (Emissivity<0.3) coating condition, the short range heater+the moly heat shield #1, the short range heater+the low emissivity (Emissivity<0.3) coating are applied.

Referring to FIG. 5, the heat shield device for low oxygen single crystal growth of the single crystal ingot growth device according to the first embodiment of the present invention,

as a heat shield device for low oxygen single crystal growth of a single crystal ingot growth device, includes:

a crucible 110 containing a silicon melt;

a graphite crucible 120 surrounding the crucible 110; and

a heat shield 130 made of a low-emissivity (Emissivity<0.3) material that surrounds a central lower portion of the graphite crucible 120 and is spaced apart from the graphite crucible 120 by a predetermined distance,

wherein molybdenum (emissivity of 0.13 to 0.19) and tungsten (emissivity 0.15˜0.28) may be used as a material with a high melting point (1600 degrees or more), which is a material with high temperature resistance, low heat absorption, and high heat reflectance (emissivity of 0.3 or less).

A connection part 140 connecting the heat shield 130 and the graphite crucible 120 is included.

A heater 150 heating a side surface of the graphite crucible 120 is further included.

The heater 150 heats the side surface of the graphite crucible 120, and in this case, heats each 25% thereof from a center thereof to upper and lower portions thereof.

The heat shield 130 includes one or more heat shielding films.

Referring to FIG. 6, the heat shield device for low oxygen single crystal growth of the single crystal ingot growth device according to the second embodiment of the present invention,

as a heat shield device for low oxygen single crystal growth of a single crystal ingot growth device, includes:

a crucible 110 containing a silicon melt; and

a graphite crucible 120 surrounding the crucible 110,

wherein a coating 160 with a low emissivity (emissivity<0.3) material is applied from a center of the graphite crucible to a lower portion thereof.

Tantalum (emissivity 0.2, Journal of Vacuum Science & Technology A 31, 011501 (2013)), TiO₂, and Si₃N₄ (emissivity 0.2 to 0.3) may be used as a high-temperature heat shield coating material.

The heater 150 heating a side surface of the graphite crucible 120 is further included.

The heater 150 heats the side surface of the graphite crucible 120, and in this case, heats each 25% thereof from a center thereof to upper and lower portions thereof.

In the first and second embodiments of the present invention, direct heat shielding is performed to lower the temperature of the bottom of the quartz crucible 110 in order to lower the oxygen concentration of the single crystal.

The heat shield may be installed to be mounted on the graphite crucible 120 surrounding the crucible 110.

Heat transfer to the crucible 110 may be suppressed by using a material having low emissivity in radiant heat transfer of the heat shield 130.

The graphite crucible 120 (emissivity of 0.8 to 0.95) absorbs about 80 to 95% of the radiant heat. The radiant heat transfer is proportional to emissivity as shown in Equation 1 below, and the lower the emissivity, the less the amount of heat transferred.

Q [symbol] ₍ [symbol] ₎=σ·α·A·T⁴ (Equation 1)

σ: Stefan Boltzmann constant, α: emissivity, A: area, T: temperature

Molybdenum (emissivity of 0.13 to 0.19) and tungsten (emissivity of 0.15˜0.28) may be used as a material with a high melting point (1600 degrees or more), which is a material with high temperature resistance, low heat absorption, and high heat reflectance (emissivity of 0.3 or less).

In addition, a material of the heat shield may be thinly processed to about 2 to 3 mm so that several layers may be overlapped and used, and the overlapping use of such a heat shield material improves heat shielding and further suppresses heat transfer to the crucible 110.

Referring to FIG. 6, the heat shield coating 160 is applied to coat the lower portion of the graphite crucible 120 surrounding the crucible 110.

Emissivity of graphite has a value of 0.95 to 0.98, and it absorbs 95 to 98% of radiated heat. The graphite crucible 120 does not absorb 70% or more of heat by applying a heat shield (emissivity of 0.3 or less) coating 160 to the graphite, but reflects it, so that the absorbed heat may be relatively reduced.

Tantalum (emissivity 0.2, Journal of Vacuum Science & Technology A 31, 011501 (2013)), TiO₂, and Si₃N₄ (emissivity 0.2 to 0.3) may be used as the heat shield coating material.

A position at which the heat shield coating 160 is applied may be obtained by applying a low emissivity coating at a height where a curvature of the quartz crucible 110 starts to lower the temperature of the bottom of the quartz crucible 110.

Through an actual simulation, the temperature at the bottom of the quartz crucible 110 when the heat shield device and the heat shield coating were applied and the concentration of oxygen flowing into the crystal were calculated.

FIG. 7 illustrates a temperature and oxygen concentration at a bottom of the crucible 110 when the heat shield 130 of the first embodiment and the heat shield coating of the second embodiment are applied.

Referring to FIG. 7, the temperatures of the bottom of the crucible 110 are shown when there is no heat shield 130 and when the moly heat shields #1 and #2 and the tantalum heat shield coating are applied, it can be seen that the temperature of the bottom of the crucible 110 decreases in the case in which the moly heat shields #1 and #2 and the tantalum heat shield coating are applied compared with the case without the heat shield 130, and it can be seen that the oxygen concentration also decreases proportionally as the temperature of the bottom of the crucible 110 decreases.

Meanwhile, when the heat shield device according to the first embodiment and the heat shield coating according to the second embodiment are used in parallel with the short range heater, a higher effect may be obtained.

Referring to FIG. 8, an oxygen concentration when a general long heater, a short range heater, a moly heat shield #1, a moly heat shield #2, a low E coating condition, the short range heater+the moly heat shield #1, the short range heater+the low E coating are applied, is shown.

it can be seen that when the heat shield device of the first embodiment is applied, a similar level of oxygen concentration reduction effect can be obtained even if a short range heater is not applied, and particularly, when a short range heater is applied to the first and second embodiments, a low oxygen concentration of 11 ppma or less may be obtained. That is, it can be seen that a lower oxygen concentration may be realized than the prior art by applying a short range heater to the first and second embodiments of the present invention that may lower the oxygen concentration in the crystal.

In the embodiment of the present invention, crystals may be grown at a substantial low oxygen concentration that suppresses the generation of oxygen by lowering the bottom temperature of the quartz crucible.

In addition, in the embodiment of the present invention, it is possible to easily secure a sufficient level of a denuded zone by lowering a density of bulk microdefects (BMD) in a semiconductor device and to reduce a concentration of oxygen flowing into a crystal during Czochralski crystal growth by reducing generation of oxygen in a quartz crucible.

In addition, in an embodiment of the present invention, the oxygen concentration may be lowered to 11 ppma or less by lowering the temperature of the bottom of the quartz crucible through the heat blocking film to reduce the generation of oxygen directly flowing into the crystal.

In addition, in the embodiment of the present invention, it is possible to grow a single crystal with a sufficiently low concentration of oxygen by overlapping several blocking films or applying the blocking film together with the short range heater and to contribute to improving yield by reducing the BMD concentration in the semiconductor device through the high-quality single crystal growth.

While this invention has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A heat shield device for low oxygen single crystal growth of a single crystal ingot growth device, comprising:
a crucible containing a silicon melt;
a graphite crucible surrounding the crucible;
a heat shield made of a low-emissivity (emissivity<0.3) material that surrounds a central lower portion of the graphite crucible and is spaced apart from the graphite crucible by a predetermined distance; and
a connection part connecting the heat shield and the graphite crucible.

2. The heat shield device for low oxygen single crystal growth of the single crystal ingot growth device of claim 1, further comprising
a heater heating a side surface of the crucible.

3. The heat shield device for low oxygen single crystal growth of the single crystal ingot growth device of claim 2, wherein
when the heater heats the side surface of the graphite crucible, it heats each 25% thereof from a center thereof to upper and lower portions thereof.

4. The heat shield device for low oxygen single crystal growth of the single crystal ingot growth device of claim 3, wherein
the heat shield includes one or more heat blocking films.

5. A heat shield device for low oxygen single crystal growth of a single crystal ingot growth device, comprising:
a crucible containing a silicon melt; and
a graphite crucible surrounding the crucible,
wherein a low emissivity (emissivity<0.3) material is coated from a center of the graphite crucible to a lower portion thereof.

6. The heat shield device for low oxygen single crystal growth of the single crystal ingot growth device of claim 5, further comprising
a heater heating a side surface of the crucible.

7. The heat shield device for low oxygen single crystal growth of the single crystal ingot growth device of claim 6, wherein
when the heater heats the side surface of the graphite crucible, it heats each 25% thereof from a center thereof to upper and lower portions thereof.
